(19) United States
(12) Patent Application Publication
(10) Pub. No.: US 2025/0012736 A1
(43) Pub. Date: Jan. 9, 2025

(54) METHOD OF OPTIMIZING OVERLAY MEASUREMENT CONDITION AND OVERLAY MEASUREMENT METHOD USING OVERLAY MEASUREMENT CONDITION

(71) Applicant: Samsung Electronics Co., Ltd., Suwon-si (KR)

(72) Inventors: Dohun Kim, Suwon-si (KR); Mincheol Kwak, Suwon-si (KR); Junseong Yoon, Suwon-si (KR); Jeongjin Lee, Suwon-si (KR); Seungyoon Lee, Suwon-si (KR); Chan Hwang, Suwon-si (KR)

(21) Appl. No.: 18/662,244

(22) Filed: May 13, 2024

(30) Foreign Application Priority Data
Jul. 3, 2023 (KR) 10-2023-0085988

(51) Int. Cl. G01N 21/956; G01N 21/95; G06T 7/00

(52) U.S. Cl. CPC G01N 21/956; G01N 21/9501; G06T 7/001; G01N 2201/126; G06T 2207/20021; G06T 2207/30148

(57) ABSTRACT

A method of optimizing an overlay measurement condition includes measuring, for each overlay measurement condition of multiple overlay measurement conditions, an overlay at multiple positions on a substrate; calculating, for each of the multiple overlay measurement conditions, key parameter indexes (KPIs) based on the measured overlay; converting, for each of the multiple overlay measurement conditions, the KPIs into key parameter function (KPF) values based on a KPF, where each of the KPFs has a same dimensional representation; integrating, for each of the multiple overlay measurement conditions, the KPF values to generate an integrated KPF value; and selecting an optimized overlay measurement condition from among the multiple overlay measurement conditions based on the integrated KPF values associated with each of the multiple overlay measurement conditions.

### CROSS-REFERENCE TO RELATED APPLICATION

This application is based on and claims priority under 35 U.S.C. § 119 to Korean Patent Application No. 10-2023-0085988, filed on Jul. 3, 2023, in the Korean Intellectual Property Office, the disclosure of which is incorporated by reference herein in its entirety.

### TECHNICAL FIELD

The present disclosure relates to an overlay measurement method. More specifically, the present disclosure relates to a method of optimizing an overlay measurement condition and an overlay measurement method using the optimized overlay measurement condition.

### BACKGROUND

A semiconductor device, or a semiconductor wafer including the semiconductor devices, includes patterns of adjacent layers that have to be accurately aligned. Accordingly, overlay measurement may be performed to align the patterns. More specifically, an overlay may refer to the degree of misalignment between two layers when an exposure process is performed on a previous layer of a semiconductor substrate and another exposure process is performed again on a next layer or a current layer after several processes are performed. In addition, correcting a relative position between layers is referred to as an overlay correction, and an overlay measurement may be performed for the overlay correction. The overlay measurement includes measuring the degree of misalignment between layers, that is, overlay misalignment or an overlay error.

### SUMMARY

The present disclosure provides a method of optimizing an overlay measurement condition for accurately measuring an overlay and an overlay measurement method using the measurement condition.

According to an aspect of the present disclosure, a method of optimizing an overlay measurement condition includes executing, by a processor, instructions stored in a non-transitory storage medium to perform operations comprising: measuring, for each overlay measurement condition of multiple overlay measurement conditions, an overlay at multiple positions on a substrate; calculating, for each of the multiple overlay measurement conditions, key parameter indexes (KPIs) based on the measured overlay; converting, for each of the multiple overlay measurement conditions, the KPIs into key parameter function (KPF) values based on a KPF, where each of the KPFs has a same dimensional representation; integrating, for each of the multiple overlay measurement conditions, the KPF values to generate an integrated KPF value; and selecting an optimized overlay measurement condition from among the multiple overlay measurement conditions based on the integrated KPF values associated with each of the multiple overlay measurement conditions.

According to another aspect of the present disclosure, an overlay measurement method includes executing, by a processor, instructions stored in a non-transitory storage medium to perform operations comprising: identifying an optimized overlay measurement condition; setting an overlay measurement recipe based on the optimized overlay measurement condition; and measuring an overlay based on the overlay measurement recipe, where identifying the optimized overlay measurement condition includes: measuring, for each overlay measurement condition of multiple overlay measurement conditions, a sample overlay at multiple positions on a substrate, calculating, for each of the multiple overlay measurement conditions, key parameter indexes (KPIs) based on the measured sample overlay, converting, for each of the multiple overlay measurement conditions, the KPIs into key parameter function (KPF) values based on a KPF, where each of the KPFs has a same dimensional representation, integrating, for each of the multiple overlay measurement conditions, the KPF values to generate an integrated KPF value, and selecting the optimized overlay measurement condition from among the multiple overlay measurement conditions based on the integrated KPF values associated with each of the multiple overlay measurement conditions.

According to another aspect of the present disclosure, a method of optimizing an overlay measurement condition includes executing, by a processor, instructions stored in a non-transitory storage medium to perform operations comprising: measuring, for each overlay measurement condition of multiple overlay measurement conditions, an overlay at multiple positions on a substrate; calculating, for each of the multiple overlay measurement conditions, key parameter indexes (KPIs) based on the measured overlay; converting, for each of the multiple overlay measurement conditions, the KPIs into a key parameter function (KPF) value by removing the dimensional representation of the multiple KPIs; integrating, for each of the multiple overlay measurement conditions, the KPF values to generate an integrated KPF value by adding the KPF values to each other; and selecting the overlay measurement condition from among the multiple overlay measurement conditions associated with a largest integrated KPF value from among the integrated KPF values.

### BRIEF DESCRIPTION OF THE DRAWINGS

Embodiments will be more clearly understood from the following detailed description taken in conjunction with the accompanying drawings in which:

FIG. 1 is a block diagram illustrating an overlay measurement system according to embodiments;

FIG. 2 is a plan view of a substrate on which a multilayer structure is formed according to an embodiment;

FIG. 3A is a plan view illustrating an image based overlay (IBO) mark used for an overlay measurement method, and FIG. 3B is a plan view illustrating a fringe based overlay (FBO) mark used for the overlay measurement method;

FIG. 4 is a schematic flowchart illustrating a method of optimizing an overlay measurement condition according to embodiments;

FIG. 5 is a schematic flowchart illustrating an overlay measurement method using an optimized overlay measurement condition according to embodiments;

FIGS. 6A, 6B, and 6C are graphs illustrating overlay performance according to an overlay measurement method of a comparative example; and

FIG. 7 is a graph illustrating overlay performance of an overlay measurement method according to an embodiment.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

The present disclosure has been described herein with reference to flowchart and/or block diagram illustrations of methods, systems, and devices in accordance with exemplary embodiments of the invention. It will be understood that each block of the flowchart and/or block diagram illustrations, and combinations of blocks in the flowchart and/or block diagram illustrations, may be implemented by computer program instructions and/or hardware operations. These computer program instructions may be provided to a processor of a general purpose computer, a special purpose computer, or other programmable data processing apparatus to produce a machine, such that the instructions, which execute via the processor of the computer or other programmable data processing apparatus, create means for implementing the functions specified in the flowchart and/or block diagram block or blocks.

These computer program instructions may also be stored in a non-transitory computer usable or computer-readable memory that may direct a computer or other programmable data processing apparatus to function in a particular manner, such that the instructions stored in the computer usable or computer-readable memory produce an article of manufacture including instructions that implement the function specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions that execute on the computer or other programmable apparatus provide steps for implementing the functions specified in the flowchart and/or block diagram block or blocks.

Hereinafter, embodiments of the present disclosure are described in detail with reference to the accompanying drawings. The same reference numerals are used for the same components in the drawings, and redundant descriptions thereof are omitted.

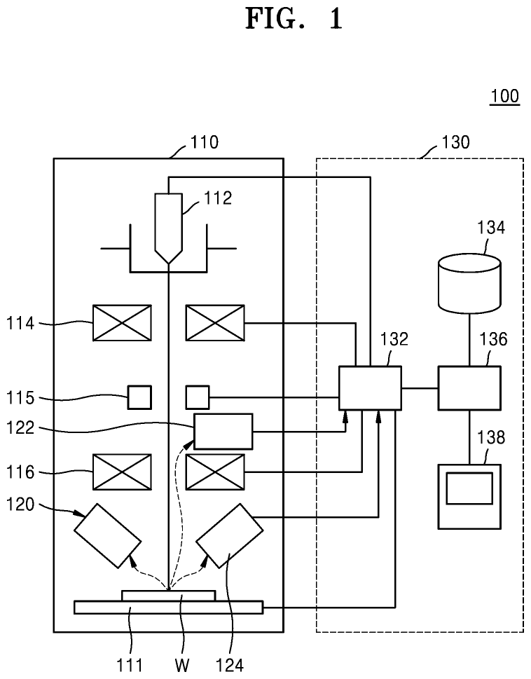

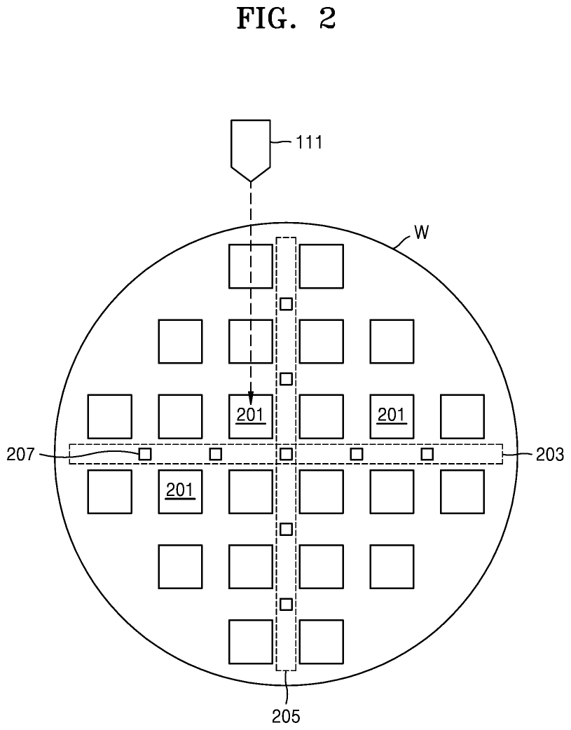

FIG. 1 is a block diagram illustrating an overlay measurement system 100 according to embodiments. FIG. 2 is a plan view of a substrate W on which a multilayer structure is formed according to an embodiment.

Referring to FIG. 1, the overlay measurement system 100 may include an electrooptical system 110 that emits an electron beam onto a substrate, such as a semiconductor substrate, on which a multilayer structure is formed, and detects the emitted electrons. The overlay measurement system 100 may include a processor 130 that acquires and analyzes an image from electrons detected by the electrooptical system 110 to calculate an overlay between an upper layer and a lower layer of the multilayer structure.

In embodiments, the overlay measurement system 100 may be used to measure an overlay between a first layer that is previously patterned and a second layer that is currently patterned in a non-destructive manner during a semiconductor manufacturing process for manufacturing semiconductor devices, such as dynamic random access memory (DRAM) and vertical NAND (VNAND).

The electrooptical system 110 of the overlay measurement system 100 may include a scanning electron microscope (SEM) for capturing an image of a substrate W that is multilayered. For example, the electrooptical system 110 may be a high-acceleration SEM. The electrooptical system 110 may include a microscope stage 111 supporting the substrate W, an electron gun 112 generating a primary electron beam, a focusing lens 114 for emitting the primary electron beam on the substrate W by controlling a direction and width of the primary electron beam, a deflector 115, an objective lens 116, and a detector 120 that detects detection signals, such as electrons emitted from the substrate W.

The processor 130 may control the operations of the overlay measurement system 100. The processor 130 may execute an operating system, applications, and so on. The processor 130 may perform the function of a central processing unit (CPU). For example, the processor 130 may control operations of an image acquirer 132, an image processor 136, a data storage 134, and an output unit 138.

Referring to FIG. 2, the substrate W may include a semiconductor wafer on which a multilayer structure is formed. Also, the substrate W may include a semiconductor wafer including a plurality of chips 201. In embodiments, memory devices may be formed in the plurality of chips 201. In embodiments, the plurality of chips 201 may include non-volatile memory devices. In embodiments, the non-volatile memory devices may each include non-volatile NAND flash memory (NAND-type flash memory). In embodiments, the non-volatile memory devices may each be any one of phase-change RAM (PRAM), magnetic RAM (MRAM), resistance RAM (ReRAM), ferroelectric RAM (FRAM), and NOR flash memory. In other embodiments, volatile memory devices, such as DRAM and static RAM (SRAM), which lose data when power is disconnected, may also be formed in the plurality of chips 201.

In embodiments, any one of a logic chip, a measurement device, a communication device, a digital signal processor (DSP), and a system-on-chip (SoC) may also be formed in each of the plurality of chips 201.

Although FIG. 2 illustrates that the plurality of chips 201 each have a substantially square profile, the present disclosure is not limited thereto. For example, the plurality of chips 201 may include driver driving integrated circuit (IC) chips, and in this case, one pair of edges of the plurality of chips 201 may be longer than another pair of edges.

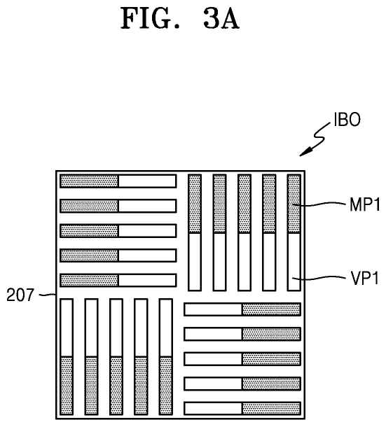

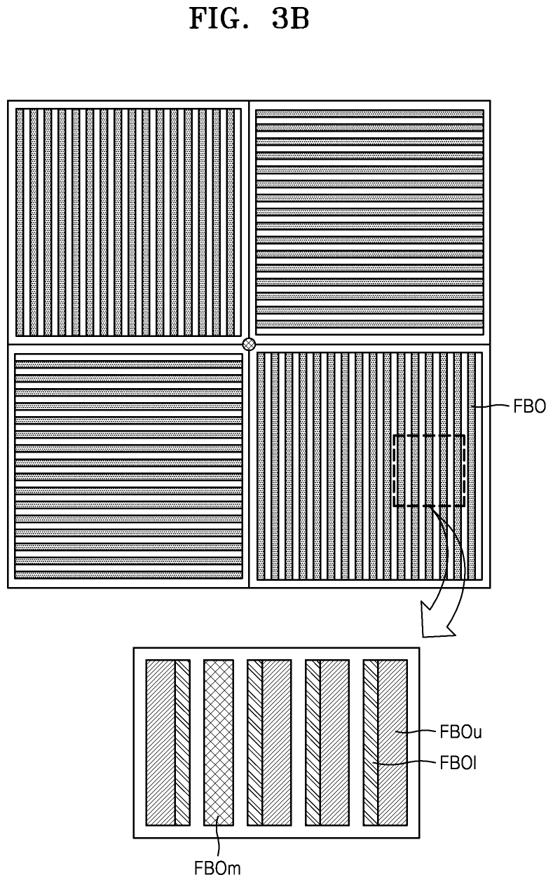

The substrate W may include the plurality of chips 201, a plurality of horizontal scribe lines 203, a plurality of vertical scribe lines 205, and a plurality of alignment marks 207. The plurality of alignment marks 207 may include, for example, an image based overlay (IBO) mark illustrated in FIG. 3A or a fringe based overlay (FBO) mark illustrated in FIG. 3B. The substrate W may have a multilayer structure in which an upper pattern and a lower pattern overlapped with each other are formed. Layers of the substrate W may include, for example, photoresist, a dielectric material, and a conductive material but are not limited thereto.

The electron gun 112 of the overlay measurement system 100 may emit an electron beam into an in-cell region of the substrate W that is multilayered. Here, the in-cell region refers to each of the plurality of chips 201, and the in-cell region may refer to a region where actual electronic components or actual patterns are formed. Accordingly, the in-cell region may refer to a region that is isolated from scribe lines 203 and 205 and does not include alignment marks 207.

In embodiments, a depth at which an electron beam penetrates the substrate W may be adjusted by adjusting an acceleration voltage of the electron beam generated by the electron gun 112 to a lower voltage or a higher voltage. For example, the electron gun 112 may generate an electron beam of an acceleration voltage of about 10 kV or more. The higher the acceleration voltage of the electron beam, the greater the depth at which the electron beam penetrates the substrate W, and accordingly, the amount of electrons emitted from a lower layer of the substrate W increases, and electrons including lower structural information may be detected.

Therefore, when an electron beam of a high landing voltage of about 10 kV or more is emitted onto the substrate W, backscattered electrons, auger electrons, and so on may be emitted from the substrate W along with secondary electrons.

Additionally, the electrooptical system 110 may include the detector 120 that detects electrons emitted from the substrate W. The detector 120 may include a first detector 122 that detects secondary electrons and a second detector 124 that detects backscattered electrons. For example, the first detector 122 may include an in-lens detector that detects secondary electrons including upper structural information of the substrate W. The second detector 124 may include a backscattered-electron detector that is adjacent to the objective lens 116 and includes lower substructural information. The detected electrons may be used to generate an actual image of the substrate W, as described below.

Accordingly, by detecting not only secondary electrons but also detecting backscattered electrons by using a highly accelerated electron beam, a cell image illustrating upper and lower structures may be acquired. That is, it is possible to acquire an actual image illustrating a structure of a lower layer of a multilayer structure as well as a structure of an upper layer of the multilayer structure. For example, an actual image illustrating a hole pattern, such as a contact hole with a high aspect ratio and a lower structure of the hole pattern, may be acquired.

The overlay measurement system 100 may include an image acquirer 132 that receives a detection signal from the detector 120 and forms an image. The image acquirer 132 may receive detection signals from the first and second detectors 122 and 124 and acquire a cell image simultaneously showing upper and lower structures of the substrate W. Also, the image acquirer 132 may be operably connected to various components of the electrooptical system 110 including the electron gun 112, the focusing lens 114, the deflector 115, the objective lens 116, and the microscope stage 111 and may control operations of the various components.

The processor 130 may control the electrooptical system 110 such that the image acquirer 132 acquires information on the upper and lower structures of the substrate W. For example, the image acquirer 132 may control acceleration voltages (a high voltage and a low voltage) of the electron gun 112, and the electrooptical system 110 emits an electron beam of a controlled acceleration voltage to penetrate the multilayered substrate W at different depths, thereby detecting electrons including structural information of each layer of the substrate W. The image acquirer 132 may acquire a cell image from the detected electrons.

In embodiments, the image acquirer 132 may divide the acquired cell image into sub-images showing different layers. For example, only a certain distribution of a gray level may be selected to divide a cell image into a first image showing an upper layer and a second image showing a lower layer. The gray level may be selected by considering thicknesses and materials of the upper and lower layers, the amount of detected electrons, and so on. Also, the cell image, the first image, and the second image may be selectively stored in the data storage 134.

In embodiments, the image processor 136 may receive data of the first image and the second image from the data storage 134. In other embodiments, the image processor 136 may receive the first image and the second image directly from the image acquirer 132.

In embodiments, the image processor 136 may calculate representative positions of upper and lower patterns from the first image and the second image and calculate a deviation of the representative position of the second image with respect to the first image. The image processor 136 may calculate a representative position of the upper pattern of the first image and a representative position for the lower pattern of the second image. For example, the image processor 136 may calculate a central position of the upper pattern from the first image and calculate a center position of the lower pattern from the second image.

The image processor 136 may match the first image to the second image and calculate an overlay of the lower pattern of the second image with respect to the upper pattern of the first image. For example, the first image may match the second image by using methods, such as image edge matching and image contrast matching.

The image processor 136 may be operably connected to the output unit 138. Overlay result values and images from the image processor 136 may be transmitted to the output unit 138. The output unit 138 may output the overlay result values on a display device.

At least one of the image acquirer 132, the image processor 136, data storage 134, and the output unit 138 illustrated in FIG. 1 may be implemented by a single computer or the processor 130 or separate module or may be implemented as separate modules using a data transmission or interfacing device. Also, the image acquirer 132, the image processor 136, and the output unit 138 may be combined with some of controllers of a semiconductor manufacturing line. Hereinafter, the plurality of alignment marks 207 and overlay measurement using the plurality of alignment marks 207 are described in more detail.

FIG. 3A is a plan view illustrating an IBO mark used for an overlay measurement method.

Referring to FIG. 3A, the alignment mark 207 of the substrate W (see FIG. 2) may be an IBO mark. For example, the alignment mark 207 may be an advanced image metrology (AIM) overlay mark. The alignment mark 207 may include a main pattern MP1 in which an external dark pattern is formed on a lower layer, and a vernier pattern VP1 in which an internal bright pattern is formed on a current layer. The main pattern MP1 and the vernier pattern VP1 may be respectively named as an outer pattern and an inner pattern based on positions of the patterns. When the alignment mark 207 is an IBO mark, an overlay may be measured by signal-processing an optical/camera image of the alignment mark 207. For example, an overlay may be measured by calculating a relative position between the main pattern MP1 and the vernier pattern VP1 by signal-processing images of the main pattern MP1 of the alignment mark 207 and the vernier pattern VP1 of the alignment mark 207.

FIG. 3B is a plan view illustrating an FBO mark used for an overlay measurement method.

Referring to FIG. 3B, the alignment mark 207 of the substrate W (see FIG. 2) may be an FBO mark. The alignment mark 207 may include a lower pattern FBOl formed on the lower layer and an upper pattern FBOu formed on the upper layer. At least a part of the lower pattern FBOl may overlap at least a part of the upper pattern FBOu in a vertical direction. In this case, at least a part of the lower pattern FBOl and at least a part of the upper pattern FBOu, which overlap each other in the vertical direction, may form a Moiré pattern FBOm. The Moiré pattern FBOm may have a Moiré cycle that is different from cycles of the lower pattern FBOl and the upper pattern FBOu due to interference between the lower pattern FBOl and the upper pattern FBOu. The alignment mark 207 may include a plurality of different Moiré patterns. For example, the alignment mark 207 may have a first Moiré pattern (not illustrated) in a partial region and may have a second Moiré pattern (not illustrated) in the other region excluding the partial region. In this case, the first Moiré pattern and the second Moiré pattern may have different Moiré cycles. When the alignment mark 207 is an FBO mark, an overlay may be measured by signal-processing an optical/camera image of the alignment mark 207. For example, an overlay may be measured by signal-processing images of the first Moiré pattern and the second Moiré pattern of the alignment mark 207 and calculating a relative position between the first Moiré pattern and the second Moiré pattern.

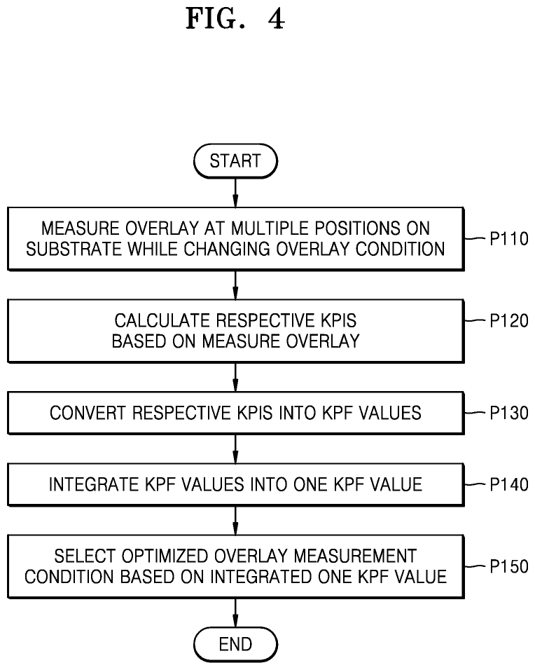

FIG. 4 is a schematic flowchart illustrating a method of optimizing an overlay measurement condition, according to embodiments.

Referring to FIG. 4, an overlay may be first measured at multiple positions of a substrate while changing a measurement condition (P110). The measurement condition may include a wavelength of a light source for overlay measurement, a focus of the light source, a relative position of the light source with respect to a substrate, environmental factors such as temperature and humidity, and the design of alignment marks on the substrate. For example, when the measurement condition is the wavelength of a light source for overlay measurement, the overlay may be measured at multiple positions on the substrate while changing the wavelength of the light source in operation P110.

The multiple positions on the substrate where the overlay is measured may be the positions where the plurality of alignment marks 207 illustrated in FIG. 2 are arranged. The number of positions on the substrate where the overlay is measured may be hundreds to thousands. For example, the number of positions on the substrate where the overlay is measured may be 100 or 200. The number of positions on the substrate may change based on the type of measurement condition. For example, the number of multiple positions on the substrate where an overlay is measured when the measurement condition is a focus of a light source is different from the number of multiple positions on the substrate where the overlay is measured when the measurement condition is a relative position of the light source.

In embodiments, overlay measurement at multiple positions on the substrate may be performed multiple times under different measurement conditions. For example, in operation P110, overlay measurement may be performed at multiple positions on the substrate while changing a wavelength of a light source, and then may be performed at multiple positions on the substrate while changing a focus of the light source. In this case, the number of positions on the substrate measured when the wavelength of the light source is changed may be different from the number of positions on the substrate measured when the focus of the light source is changed.

In one embodiment, operation P110 may be performed on a plurality of substrates rather than one substrate. For example, operation P110 may be performed on two substrates.

After performing operation P110, a key parameter index (KPI) may be calculated based on the measured overlay (P120). The KPI refers to an overlay performance indicator in which overlay performance according to an overlay measurement condition is reflected. For example, when overlay measurement is performed by using a wavelength of a light source as a measurement condition, the KPI refers to an overlay performance index in which the overlay performance according to the wavelength of the light source is reflected. In this case, the overlay performance indicator may refer to, for example, the quality of an overlay image measured according to a change in the wavelength of the light source. Here, the quality of the overlay image may include, for example, brightness or so on of the overlay image. In another example, the overlay performance index may also refer to the degree of defect or so on of an alignment mark. As the overlay measurement condition changes, the KPI calculated based on the measured overlay may also change. For example, when the overlay measurement condition is the wavelength of the light source, a KPI that is calculated may also change as the overlay measurement condition, that is, the wavelength of the light source, changes.

In embodiments, operation P120 may be performed multiple times. For example, when overlay measurement is performed in two types of overlay measurement conditions in operation P110, operation P120 may be performed twice based on the overlay measurement according to each overlay measurement condition, and two KPIs may be calculated.

In embodiments, a method of calculating the KPI may change according to the overlay measurement condition or the overlay performance indicator defined by the KPI. For example, when two KPIs are calculated as described above, each KPI may be calculated in a different way according to the overlay measurement condition or the overlay performance index defined by each KPI.

Interpretation of the KPI may change based on the type of overlay measurement condition. For example, it can be interpreted that overlay performance is acceptable as a first KPI according to a first overlay measurement condition is less and the overlay performance is acceptable as a second KPI according to a second overlay measurement condition is greater.

After performing operation P120, the calculated KPI may be converted into a key performance function (KPF) value (P130).

Here, the KPF is a function that uses the KPI calculated in operation P120 as a variable, and is a function for equalizing respective KPIs calculated in operation P120. The KPF may be defined such that the dimensional representations of the KPIs may be equalized based on the overlay performance indicators defined by the KPIs. When the KPF values converted from the respective KPIs by the KPF are greater, the overlay performance may be interpreted to be acceptable. In this case, for example, when the overlay performance is interpreted to be acceptable when the first KPI value is relatively smaller, as the first KPF value may be converted to have a greater value due to an inversely proportional relationship between the first KPI value and the KPF value. In addition, when the overlay performance is interpreted to be acceptable when the second KPI value is relatively larger, as the second KPF value may be converted to have a greater value due to a proportional relationship between the second KPI value and the KPF value.

In embodiments, the KPF may change based on the types of KPIs calculated in operation P120. For example, when two KPIs are calculated in operation P120, the first KPF that converts the first KPI may be different from the second KPF that converts the second KPI.

In embodiments, the KPF may be a function for nondimensionalizing (e.g., the full removal of dimensional representations or a partial removal of dimensional representations and a corresponding suitable substitution of dimensional representations) the KPI calculated in operation P120. For example, when the KPI value has a nanometer unit, the KPF value converted from the KPI value by a corresponding KPF may be a dimensionless value of an offset nanometer unit.

In embodiments, operation P130 may be performed multiple times. For example, when a plurality of KPIs are calculated by performing operation P120 multiple times, operation P130 may be performed multiple times on the plurality of KPIs, and accordingly, the plurality of KPIs may be converted into corresponding KPF values.

After operation P130 is performed, the KPF values may be integrated to generate an integrated KPF value (P140).

Here, the integrated KPF value may refer to a KPF value including KPF values calculated according to operation P130 and may be referred to as “KPFt” unless specifically defined below. KPFt may be obtained by equation (1) below.

$$F ( 〚 KPI 〛 \_ 1 , 〚 KPI 〛 \_ 2 , 〚 KPI 〛 \_ 3 , … , 〚 KPI 〛 \_n ) = w\_ 1 * f\_ 1 ( 〚 KPI 〛 \_ 1 ) + w\_ 2 * f\_ 2 ( 〚 KPI 〛 \_ 2 ) + w\_ 3 * f\_ 3 ( 〚 KPI 〛 \_ 3 ) + … + f\_n * fn ( 〚 KPI 〛 \_n ) \qquad Equation ( 1 )$$

In the above equation, F (KPI1, KPI2, KPI3, . . . , KPIn) refers to the integrated KPF, that is, KPFt; f1(KPI1), . . . , and fn (KPIn) refer to KPF values calculated in operation P130; and w1, . . . , and wn refer to weighted values of KPFs. That is, an operation of integrating respective KPF values into one KPF may be performed by assigning weighted values to the respective KPF values and adding all of the KPF values to which the weighted values are assigned. In this case, the weighted values may be set differently based on alignment marks of a substrate and/or measurement equipment. As described above in operation P130, the respective KPF values are obtained by equalizing dimensional representations of respective KPI values (for example, dimensionless values). Accordingly, unlike the KPIs that may have different dimensional representations, all of the KPF values have the same dimensional representation and may be converted into one integrated KPF value.

After operation P140 is performed, optimized overlay measurement conditions may be selected based on the integrated KPF (P150). Operation P150 may be performed by determining an overlay measurement condition in which the integrated KPF value (that is, KPFt) is maximized and setting the integrated KPF value as an actual overlay measurement condition. This is because, as described above, each KPF value is converted from the KPI value to have a greater value when interpreted to have an acceptable overlay performance.

Conventionally, a plurality of KPI values with different dimensional representations could not be integrated with each other, and accordingly, the plurality of KPI values were considered independently to optimize an overlay measurement condition. However, in this case, the optimization time is increased because the measurement condition is optimized by individually considering a plurality of overlay performance indicators. Also, there are limitations to optimization because a plurality of overlay performance indicators that affect overlay performance may not be considered simultaneously.

In addition, a method of optimizing an overlay measurement condition according to an embodiment may simultaneously consider a plurality of overlay performance indicators through one integrated KPF, and thus, optimization time is reduced and improved optimization of overlay measurement conditions may be performed.

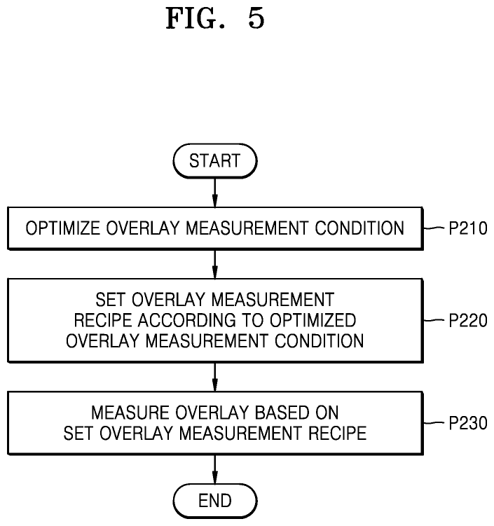

FIG. 5 is a schematic flowchart illustrating an overlay measurement method using an optimized overlay measurement condition according to embodiments.

Referring to FIG. 5, an overlay measurement condition may first be optimized (P210). An operation of optimizing an overlay measurement condition (P210) may be substantially the same as the method of optimizing an overlay measurement condition described with reference to FIG. 4. That is, an operation of optimizing the overlay measurement condition (P210) may include the operation of measuring an overlay at multiple positions on a substrate while changing a measurement condition (P110), the operation of calculating a KPI based on the measured overlay (P120), the operation of converting the KPI into a KPF (P130), the operation of converting respective KPFs into the integrated KPF (P140), and the operation of selecting an optimized overlay measurement condition based on the integrated KPF (P150).

After operation P210 is performed, an overlay measurement recipe may be set according to the optimized overlay measurement condition (P220). The overlay measurement recipe may refer to setting values of various overlay measurement conditions used during overlay measurement. For example, the overlay measurement recipe may include wavelengths of a light source used for measurement, foci of the light source, measurement position, measurement time, and so on. Here, setting of the overlay measurement recipe may refer to setting of the overlay measurement system 100 illustrated in FIG. 1 that performs overlay measurement.

After operation P220 is performed, an overlay may be measured based on the set overlay measurement recipe (P230). Here, the overlay measurement may refer to, for example, overlay measurement of alignment marks on a substrate for overlay measurement.

In embodiments, the overlay measurement method may further include an operation of feeding back the overlay measurement condition based on the overlay obtained by performing operation P230.

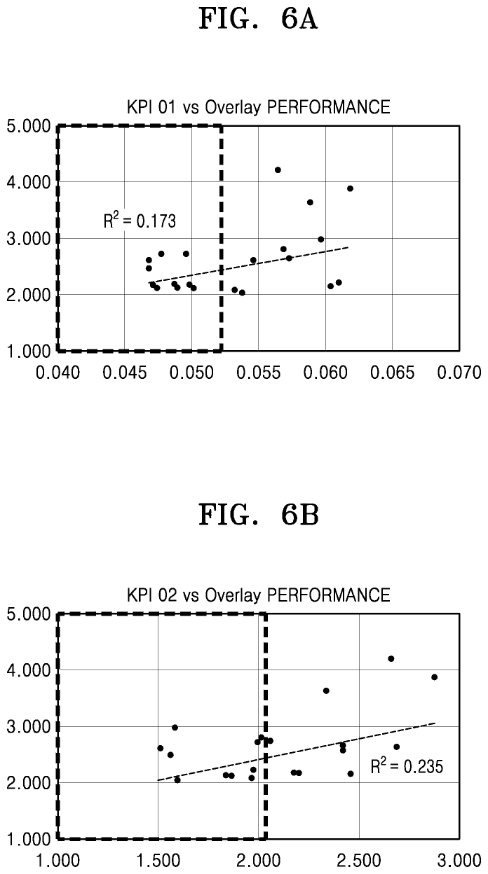

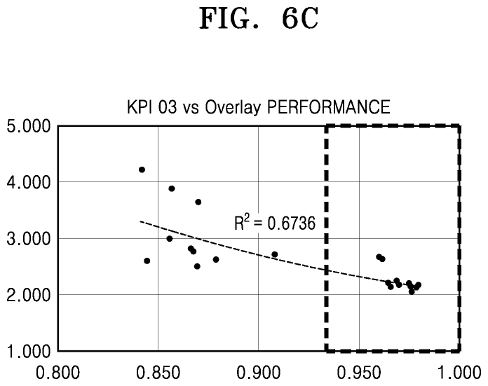

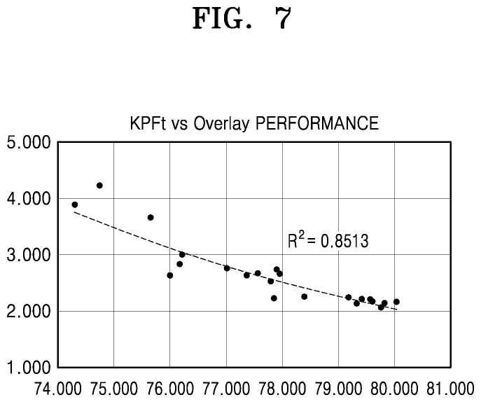

The overlay measurement method according to embodiments may optimize an overlay measurement condition based on the integrated KPF, set an overlay measurement recipe according to the optimized overlay measurement condition, and measure an overlay based on the set overlay measurement recipe. Accordingly, rapid and improved overlay measurement may be performed. Hereinafter, an overlay measurement method according to a comparative example is compared with the overlay measurement method illustrated in FIG. 5 with reference to FIGS. 6A-6C and 7.

FIGS. 6A-6C are graphs illustrating overlay performance according to an overlay measurement method of a comparative example, and FIG. 7 is a graph illustrating overlay performance according to the overlay measurement method of an embodiment. Specifically, FIGS. 6A-6C illustrate overlay performance of an overlay measurement method based on an overlay measurement condition optimized by using KPI values, and FIG. 7 illustrates overlay performance of an overlay measurement method based on an overlay measurement condition optimized by using one integrated KPF value. FIGS. 6A, 6B, and 6C respectively illustrate a KPI value for brightness of a pattern included in alignment marks, a KPI value for a defect in the alignment marks, and a KPI value for a periodic signal of the pattern, and in FIGS. 6A to 7, the closer the R2 value is to 1, the more the overlay measurement condition is optimized according to the KPI value or the KPF value is related to the overlay performance.

It can be seen that, referring to FIGS. 6A to 6C, the R2 values are respectively 0.173, 0.235, and 0,6736 and, referring to FIG. 7, the R2 value is 0.8513. That is, referring to FIGS. 6A to 7, it can be seen that an overlay measurement condition optimized according to the respective KPI values in FIGS. 6A to 6C is relatively less related to overlay performance and an overlay measurement condition optimized according to one integrated KPF value in FIG. 7 is relatively more related to overlay performance. That is, it can be seen that, when an overlay measurement condition is selected according to one integrated KPF value, overlay performance may be further improved.

As above, embodiments are disclosed in the drawings and specification. In the present specification, embodiments are described by using certain terms, but these are used only for the purpose of describing the present disclosure and are not used to limit the meaning or scope of the present disclosure described in the claims. Therefore, those skilled in the art to which the present disclosure belongs will understand that various modifications and other equivalent embodiments may be derived therefrom. Therefore, the true technical protection scope of the present disclosure should be determined by the technical idea of the attached claims.

While the present disclosure has been particularly shown and described with reference to embodiments thereof, it will be understood that various changes in form and details may be made therein without departing from the spirit and scope of the following claims.

What is claimed is:

1. A method of optimizing an overlay measurement condition, the method comprising:
executing, by a processor, instructions stored in a non-transitory storage medium to perform operations comprising:
measuring, for each overlay measurement condition of multiple overlay measurement conditions, an overlay at multiple positions of a substrate;
calculating, for each of the multiple overlay measurement conditions, key parameter indexes (KPIs) based on the measured overlay;
converting, for each of the multiple overlay measurement conditions, the KPIs into key parameter function (KPF) values based on a KPF, wherein each of the KPFs has a same dimensional representation;
integrating, for each of the multiple overlay measurement conditions, the KPF values to generate an integrated KPF value; and
selecting an optimized overlay measurement condition from among the multiple overlay measurement conditions based on the integrated KPF values associated with each of the multiple overlay measurement conditions.

2. The method of claim 1, wherein the KPF is based on the multiple overlay measurement conditions.

3. The method of claim 1, wherein the KPF converts a respective dimensional representation of the KPIs to the same dimensional representation based on the multiple overlay measurement conditions.

4. The method of claim 1, wherein integrating the KPF values to generate the integrated KPF value further comprises adding each of the KPF values to each other.

5. The method of claim 1, wherein integrating the KPF values to generate the integrated KPF value further comprises assigning a weighted value to each of the KPF values.

6. The method of claim 1, wherein selecting the optimized overlay measurement condition further comprises identifying an overlay measurement condition from among the multiple overlay measurement conditions that is associated with a largest integrated KPF value from among the integrated KPF values.

7. The method of claim 1, wherein the multiple positions are associated with alignment marks of the substrate, and wherein the alignment marks comprise at least one of an image based overlay (IBO) and a fringe based overlay (FBO).

8. The method of claim 7, wherein the multiple overlay measurement conditions comprise at least one of a wavelength of a light source, a focus of the light source, and a design of the alignment marks.

9. The method of claim 1, further comprising measuring the overlay on multiple substrates.

10. The method of claim 1, wherein a number of the multiple positions is based on the multiple overlay measurement conditions.

11. An overlay measurement method comprising:
executing, by a processor, instructions stored in a non-transitory storage medium to perform operations comprising:
identifying an optimized overlay measurement condition;
setting an overlay measurement recipe based on the optimized overlay measurement condition; and
measuring an overlay based on the overlay measurement recipe,
wherein identifying the optimized overlay measurement condition comprises:
measuring, for each overlay measurement condition of multiple overlay measurement conditions, a sample overlay at multiple positions of a substrate,
calculating, for each of the multiple overlay measurement conditions, key parameter indexes (KPIs) based on the measured sample overlay,
converting, for each of the multiple overlay measurement conditions, the KPIs into key parameter function (KPF) values based on a KPF, wherein each of the KPIs has a same dimensional representation,
integrating, for each of the multiple overlay measurement conditions, the KPF values to generate an integrated KPF value, and
selecting the optimized overlay measurement condition from among the multiple overlay measurement conditions based on the integrated KPF values associated with each of the multiple overlay measurement conditions.

12. The overlay measurement method of claim 11, wherein the KPF is based on the multiple overlay measurement conditions.

13. The overlay measurement method of claim 11, wherein the KPF converts a respective dimensional representation of the KPIs to the same dimensional representation based on the multiple overlay measurement conditions.

14. The overlay measurement method of claim 11, wherein integrating the KPF values to generate the integrated KPF value further comprises assigning weighted values to the KPF values and adding each of the weighted KPF values to each other.

15. The overlay measurement method of claim 14, wherein the optimized overlay measurement condition is associated with a largest integrated KPF value from among the integrated KPF values.

16. The overlay measurement method of claim 11, further comprising measuring the sample overlay of multiple substrates, and a number of the multiple positions is based on the multiple overlay measurement conditions.

17. The overlay measurement method of claim 11, further comprising feeding back the overlay measurement condition associated with the overlay measured that is based on the overlay measurement recipe.

18. A method of optimizing an overlay measurement condition, the method comprising:
executing, by a processor, instructions stored in a non-transitory storage medium to perform operations comprising:
measuring, for each overlay measurement condition of multiple overlay measurement conditions, an overlay at multiple positions on a substrate;
calculating, for each of the multiple overlay measurement conditions, key parameter indexes (KPIs) based on the measured overlay;
converting, for each of the multiple overlay measurement conditions, the KPIs into a key parameter function (KPF) value by removing the dimensional representation of the KPIs;
integrating, for each of the multiple overlay measurement conditions, the KPF values to generate an integrated KPF value by adding the KPF values to each other; and
selecting the overlay measurement condition from among the multiple overlay measurement conditions associated with a largest integrated KPF value from among the integrated KPF values.

19. The method of claim 18, wherein the KPIs have different dimensional representations.

20. The method of claim 18, wherein integrating the KPF values to generate the integrated KPF value further comprises assigning a weighted value to each of the KPF values.
